(19) United States
(12) Patent Application Publication
(10) Pub. No.: US 2008/0144405 A1
(43) Pub. Date: Jun. 19, 2008

(54) Data strobe timing compensation

(75) Inventors: Chee Hak Teh, Penang (MY); Suryaprasad Kareenahalli, Folsom, CA (US); Zohar Bogin, Folsom, CA (US)

Correspondence Address: INTEL/BLAKELY, 1279 OAKMEAD PARKWAY, SUNNYVALE, CA, 94085-4040, US

(73) Assignee: Intel Corporation

(21) Appl. No.: 11/642,318

(22) Filed: Dec. 18, 2006

(51) Int. Cl. G11C 7/10

(52) U.S. Cl. 365/193

(57) ABSTRACT

A method, apparatus, and system are disclosed. In one embodiment, the method receiving data from a memory on a first interconnect of at least one interconnect, receiving a source-synchronous data strobe from the memory, creating at least a nominal, an early, and a delayed compensated data strobe from the received data strobe, latching the received data with the nominal, early, or delayed compensated data strobe, outputting the latched data onto one or more of the at least one interconnect.

### FIELD OF THE INVENTION

The invention relates to memory. More specifically, the invention relates to the timing of data and the corresponding data strobe from memory.

### BACKGROUND OF THE INVENTION

Processors in computer systems increase in execution speed on a regular basis. This speed increase has a number of consequences, one of which is similar required increase in the speed of the system memory that the processor utilizes. To keep up with processor requirements, memory technologies have been implementing different varieties of speed increases. One of these technologies is double data rate (DDR) memory, which utilizes both the rising and falling edge of the memory clock to perform memory operations.

An increasingly common implementation of the latest DDR memories (E.g. DDR2 or DDR3) has been to have a source synchronous data strobe with the data. The data strobe signal is the signal that transports the memory clock information (i.e. the rising and falling edge of the data strobe correspond to the rising and falling edge of the memory clock. Thus, the data strobe, which controls the valid latching of the data on the processor-memory interconnect, originates from the memory itself alongside the corresponding data. As the frequencies of DDR2 and DDR3 memories increase, the length of time any piece of data is valid on the interconnect decreases. This limited time for valid data requires much more precise interconnect layouts. There is very little tolerance for data and data strobe mismatched timing.

### BRIEF DESCRIPTION OF THE DRAWINGS

The present invention is illustrated by way of example and is not limited by the figures of the accompanying drawings, in which like references indicate similar elements, and in which:

FIG. 1 is a block diagram of a computer system which may be used with embodiments of the present invention.

FIG. 2 illustrates an overview of one embodiment of the components within the Data Strobe Tolerance Logic Unit.

FIG. 3 illustrates one embodiment of the detailed circuitry within the Data Window Enlargement and Data Strobe Divider.

FIG. 4 illustrates one embodiment of the nominal timing of the divide-by-two strobes 0-3 in relation to the original data strobe input into the Data Window Enlargement and Data Strobe Divider.

FIG. 5 illustrates one embodiment of the detailed circuitry within the Data Strobe Margin Compensation Driver and the Data Strobe Margin Compensation Receiver.

FIG. 6 illustrates a timing diagram of one embodiment of the compensated divide-by-two strobes, the data, and the latch enables in a nominal strobe timing mode.

FIG. 7 illustrates a timing diagram of one embodiment of the compensated divide-by-two strobes, the data, and the latch enables in a delayed strobe timing mode.

FIG. 8 illustrates a timing diagram of one embodiment of the compensated divide-by-two strobes, the data, and the latch enables in an early strobe timing mode.

FIG. 9 is a flow diagram of one embodiment of a process to compensate for mismatched timing between data and a source synchronous data strobe.

### DETAILED DESCRIPTION OF THE INVENTION

Embodiments of a method, apparatus, and system to compensate for a timing mismatch between data and a source-synchronous data strobe are described. In the following description, numerous specific details are set forth. However, it is understood that embodiments may be practiced without these specific details. In other instances, well-known elements, specifications, and protocols have not been discussed in detail in order to avoid obscuring the present invention.

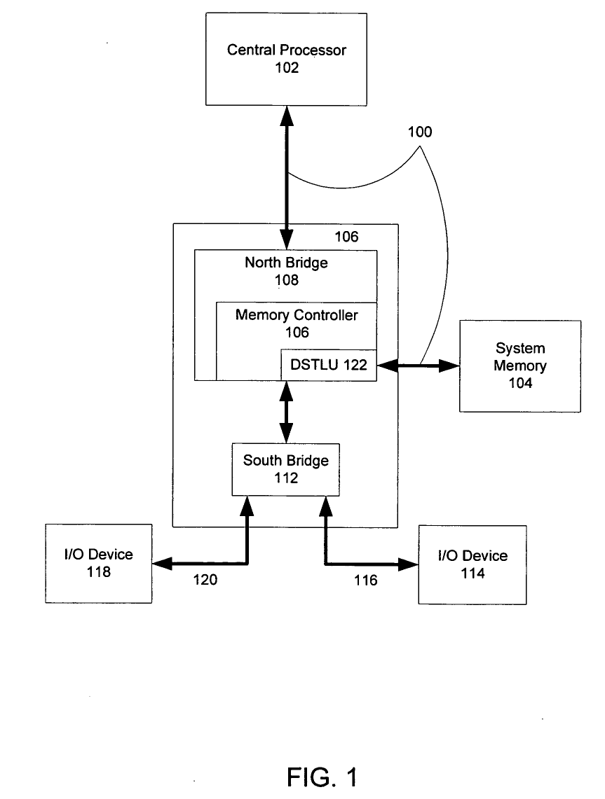

FIG. 1 is a block diagram of a computer system which may be used with embodiments of the present invention. The computer system comprises a processor-memory interconnect 100 for communication between different agents coupled to interconnect 100, such as processors, bridges, memory devices, etc. Processor-memory interconnect 100 includes specific interconnect lines that send arbitration, address, data, and control information (not shown). In one embodiment, central processor 102 is coupled to processor-memory interconnect 100. In another embodiment, there are multiple central processors coupled to processor-memory interconnect (multiple processors are not shown in this figure).

Processor-memory interconnect 100 provides the central processor 102 and other devices access to the system memory 104. A system memory controller 106 controls access to the system memory 104. In one embodiment, the system memory controller is located within the north bridge 108 of a chipset 110 that is coupled to processor-memory interconnect 100. In another embodiment, a system memory controller is located on the same chip as central processor 102 (not shown). Information, instructions, and other data may be stored in system memory 104 for use by central processor 102 as well as many other potential devices. I/O devices, such as I/O devices 114 and 118, are coupled to the south bridge 112 of the chipset 106 through one or more I/O interconnects 116 and 120.

In one embodiment, the system memory 104 is source synchronous. In this embodiment, the system memory outputs a data strobe, in addition to the data, to memory controller 106 across processor-memory interconnect 100. The source synchronous data strobe and data require a close timing match to maintain valid data. In different embodiments, the system memory 104 may comprise double data rate 2 (DDR2) memory or DDR3 memory. With DDR2 and DDR3 memory, the timing match between a source synchronous data strobe and the corresponding data requires even greater matching precision. DDR2, DDR3, and other high-speed DDR memories send data across processor memory interconnect every half clock (I.e. every rising and falling edge of the data strobe). Thus, currently, the width of the window allowable to match data on the interconnect with the corresponding rising or falling edge of the data strobe is 0.5 clock cycles.

In one embodiment, the computer system in FIG. 1 has a Data Strobe Tolerance Logic Unit 122 located within the memory controller 106. The Data Strobe Tolerance Logic Unit 122 has circuitry to allow for continued high-speed data throughput across processor-memory interconnect 100 while increasing the data and data strobe matching window to 2 clock cycles.

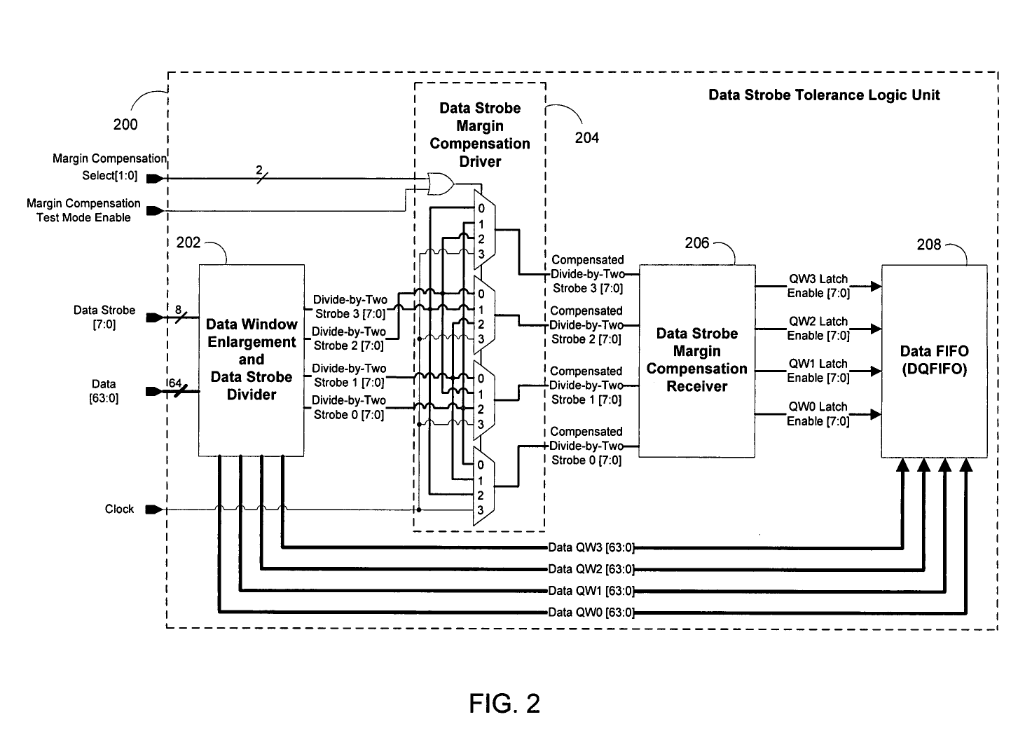

FIG. 2 illustrates an overview of one embodiment of the components within the Data Strobe Tolerance Logic Unit 200. In this embodiment, the data strobe and the data are input into the Data Strobe Tolerance Logic Unit 200. In one embodiment, the data enters via a 64-bit data bus that is comprised of 8 byte lanes. Additionally, in one embodiment, the data strobe is an 8-bit value where each strobe bit corresponds to one of the eight byte lanes on the data interconnect.

The data strobe and the data are input into a Data Window Enlargement and Data Strobe Divider 202. The Data Window Enlargement and Data Strobe Divider 202 is located within the Data Strobe Tolerance and Logic Unit 200. In one embodiment, the Data Window Enlargement and Data Strobe Divider 202 takes the 8-bit data strobe and splits it into four separate staggered versions. In this embodiment, each of the staggered data strobes are stretched so that each full clock cycle of a stretched data strobe is a divide-by-two cycle of the original data strobe. Furthermore, the four strobes are quad-staggered so that the first strobe's rising edge is one-half of the input original data strobe clock cycle before the rising edge of the second strobe, the second strobe's rising edge is one-half of the original data strobe clock cycle before the rising edge of the third strobe, and so on. Thus, the divide-by-two data strobes have clock cycles that are twice as long as the original data strobe clock cycle and are quad-staggered, each being a half of an original data strobe clock cycle apart from each adjacent strobe. This allows for the tolerance of a data/data strobe mismatch to increase to four times the original tolerance level (I.e. from 0.5 memory clock cycle tolerance to 2 memory clock cycle tolerance).

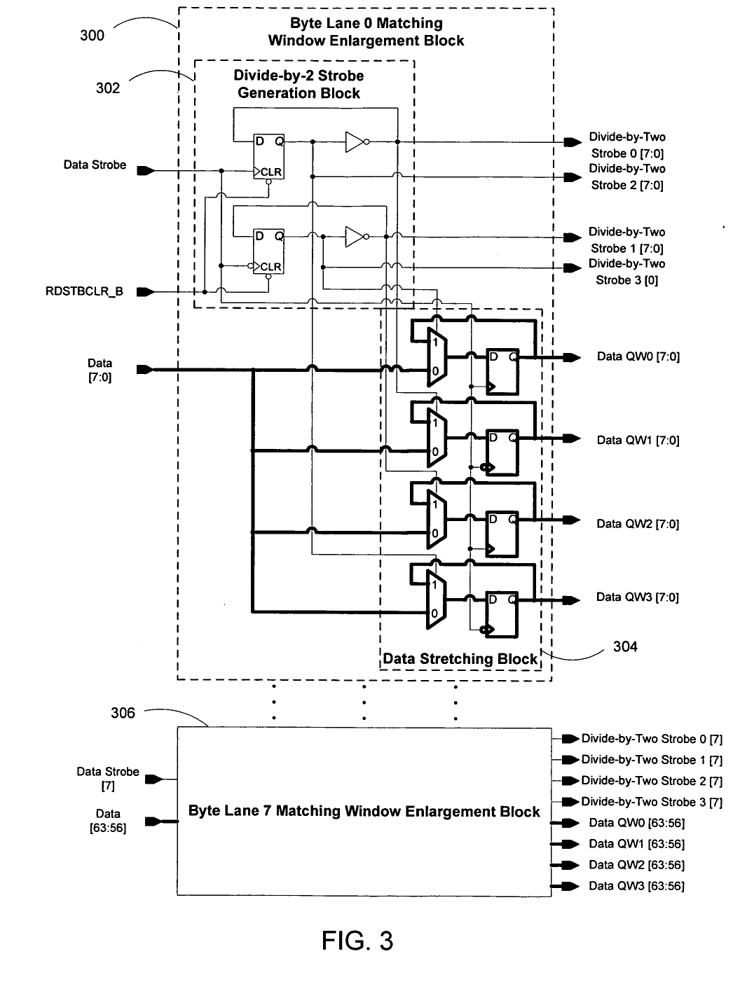

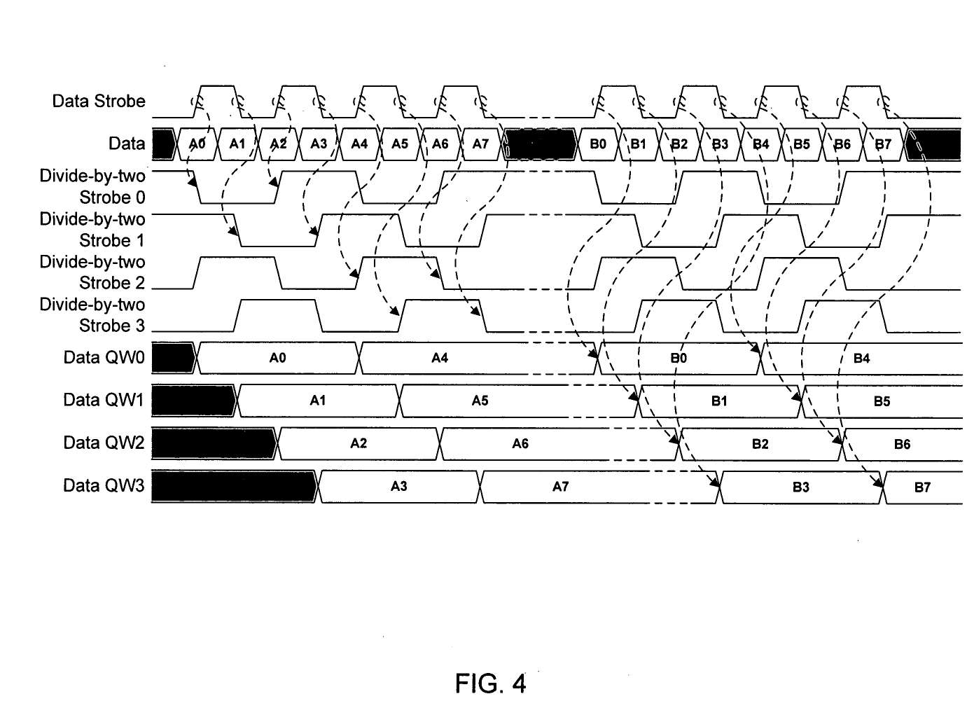

FIG. 3 illustrates one embodiment of the detailed circuitry within the Data Window Enlargement and Data Strobe Divider. The Data Window Enlargement and Data Strobe Divider has eight byte lane Matching Window Enlargement Blocks. Each enlargement block (E.g. block 300 is for byte lane 0) has a Divide-By-Two Strobe Generation Block 302. The Divide-By-Two Strobe Generation Block 302 stretches the data strobe for its corresponding byte lane by using the input data strobe to clock two separate toggle-flops, a positive edge and a negative edge toggle-flop. In one embodiment, the input data strobe has been stripped of strobe tri-states. The Divide-By-Two Strobe Generation Block 302 outputs the four divide-by-two data strobes. The divide-by-two data strobe outputs are additionally input into a Data Stretching Block 304. The Data Stretching Block 304 takes the input data, uses divide-by-two strobes 0-3 as a mask to stretch the 0.5 memory clock wide data into a 2 memory clock wide quad-staggered data. The stretching is achieved via sampling the incoming 0.5 memory clock wide data on every other rising or falling edge of the data strobe using the divide-by-2 data strobe as a data mask. FIG. 4 illustrates one embodiment of the nominal timing of the divide-by-two strobes 0-3 in relation to the original data strobe input into the Data Window Enlargement and Data Strobe Divider. Thus, the stretched data is split onto four separate internal data interconnects 0-3.

Returning to FIG. 2, in this embodiment, the Data Window Enlargement and Data Strobe Divider 202 splits out the data onto four separate 64-bit wide output interconnects within the Data Strobe Tolerance Logic Unit 200: Internal Data Interconnect 0, Internal Data Interconnect 1, Internal Data Interconnect 2, and Internal Data Interconnect 3. When a memory read occurs, it results in a cache line being received from system memory. In one embodiment, the cache line is 64-bytes wide. Thus, a memory read would result in eight consecutive quad-words being received from the processor-memory interconnect. The four data interconnect can be viewed as “internal” because in one embodiment, they are internal to the Data Strobe Tolerance Logic Unit 200. In other embodiments, if the data FIFO is implemented external to the Data Strobe Tolerance Logic Unit, then the four interconnects may not be internal or may be just partially internal to the Data Strobe Tolerance Logic Unit.

In the embodiment illustrated in FIG. 2, the Data Window Enlargement and Data Strobe Divider 202 sends every fourth quad-word received from a cache line read onto each of the four Internal Data Interconnects. For example, quad-word (QW) 0 is sent on Internal Data Interconnect 0, QW1 is sent on Internal Data Interconnect 1, QW2 is sent on Internal Data Interconnect 2, and QW3 is sent on Internal Data Interconnect 3. Then QW4 is sent on Internal Data Interconnect 0, QW5 is sent on Internal Data Interconnect 1, QW6 is sent on Internal Data Interconnect 2, and QW7 is sent on Internal Data Interconnect 3. Therefore, each QW is held valid on its corresponding Internal Data Interconnect for three more received QWs. This allows each QW to be held valid on the bus at least four times as long as the non-split or staggered original data strobe timing. Since each read represents a cache line, there are 8 QWs input for each read when the cache line is 64 bytes wide. Thus, in this embodiment, Internal Data Interconnects 0-3 each have two consecutive QWs for each memory read. In one embodiment, the first of the two QWs on each Internal Data Interconnect (E.g. QW0 on Internal Data Interconnect 0) is held valid for two complete data strobe cycles. On the other hand, the second of the two QWs on each Internal Data Interconnect (E.g. QW4 on Internal Data Interconnect 0) may be held valid on the relevant Internal Data Interconnect until a subsequent memory read is initiated. At that point, the second QW of data relating to the first memory read on the given Internal Data Interconnect is replaced by the first QW of data relating to the second memory read on that Internal Data Interconnect.

The four divide-by-two strobe outputs from the Data Window Enlargement and Data Strobe Divider 202 are then input into the Data Strobe Margin Compensation Driver 204. In one embodiment, the Data Strobe Margin Compensation Driver 204 receives the four divide-by-two strobe outputs from the Data Window Enlargement and Data Strobe Divider 202 as inputs. Furthermore, in this embodiment, the Data Strobe Margin Compensation Driver 204 also receives a 2-bit Margin Compensation Select value and a 1-bit Margin Compensation Test Mode Enable value as additional inputs. When the Margin Compensation Test Mode Enable bit is set, a clock is substituted for the strobes to allow the latches and flops to be scanned accurately and reliably in test mode. The test mode clock may be implemented in any of a number of ways in different embodiments (not shown). Additionally, the Margin Compensation Select value determines whether the divide-by-two strobes will operate at nominal timing (i.e. the incoming data strobe and incoming data are already matched), delayed timing (i.e. the incoming data is delayed in regard to its corresponding data strobe when it reaches the data FIFO), or early timing (I.e. the incoming data is early in regard to its corresponding data strobe when it reaches the data FIFO). Table 1 illustrates the available Margin Compensation Select values and the corresponding data strobe timing.

TABLE 1
Margin Compensation Select Timing Values

| Margin Compensation Select Value | Modified Data Strobe Timing |
|---|---|
| 00b | Nominal |
| 01b | Delayed |
| 10b | Early |
| 11b | Test Mode |

Therefore, if the data strobe and data arrive at the Data Strobe Tolerance and Logic Unit from the memory and are matched then the Margin Compensation Select value will be 00b. If the incoming data is delayed in regard to its corresponding data strobe when it arrives at the data FIFO, the Margin Compensation Select value will be 01b, which will utilize delayed divide-by-two strobe settings to compensate for the delayed data. Finally, if the incoming data is early and arrives before its corresponding data strobe, the Margin Compensation Select value will be 10b, which will utilize early divide-by-two strobe settings to compensate for the early data.

The quad-staggered divide-by-two strobes that enter the Data Strobe Margin Compensation Driver 204 are then multiplexed and sent out from the Data Strobe Margin Compensation Driver 204 as compensated divide-by-two strobes 0-3. The Data Strobe Margin Compensation Receiver 206 receives the compensated divide-by-two strobes 0-3 as well as the Margin Compensation Select value. The specific version of the compensated divide-by-two strobes 0-3 is selected by using the compensated divide-by-two strobes value input into the Data Strobe Margin Compensation Receiver 206 as either the nominal, early, or delayed version of the quad-staggered divide-by-two strobes.

The Internal Data Interconnects couple the Data Window Enlargement and Data Strobe Divider 202 to a data first-in-first-out (FIFO) buffer 208. The buffer 208 is used to temporarily store the read data sent onto Internal Data Interconnects 0-3 from the Data Window Enlargement and Data Strobe Divider 202. The Data Strobe Margin Compensation Receiver 206 utilizes the selected version of the compensated divide-by-two strobes (nominal, early, or delayed) to generate latch enables that latch the data from the Internal Data Interconnects 0-3. The buffer 208 utilizes the generated latch enables to latch the data from Internal Data Interconnects 0-3 into a specific location within the buffer. In one embodiment, the FIFO buffers for each of four QWs are eight storage locations deep. Thus, the data from the processor-memory interconnect may be more reliably sampled because of a larger matching window and a compensated data strobe that may be early or late with respect to its corresponding data. In different embodiments, the data in the buffer 208 may be utilized by the memory read requesting agent for use once the data has been reliably latched.

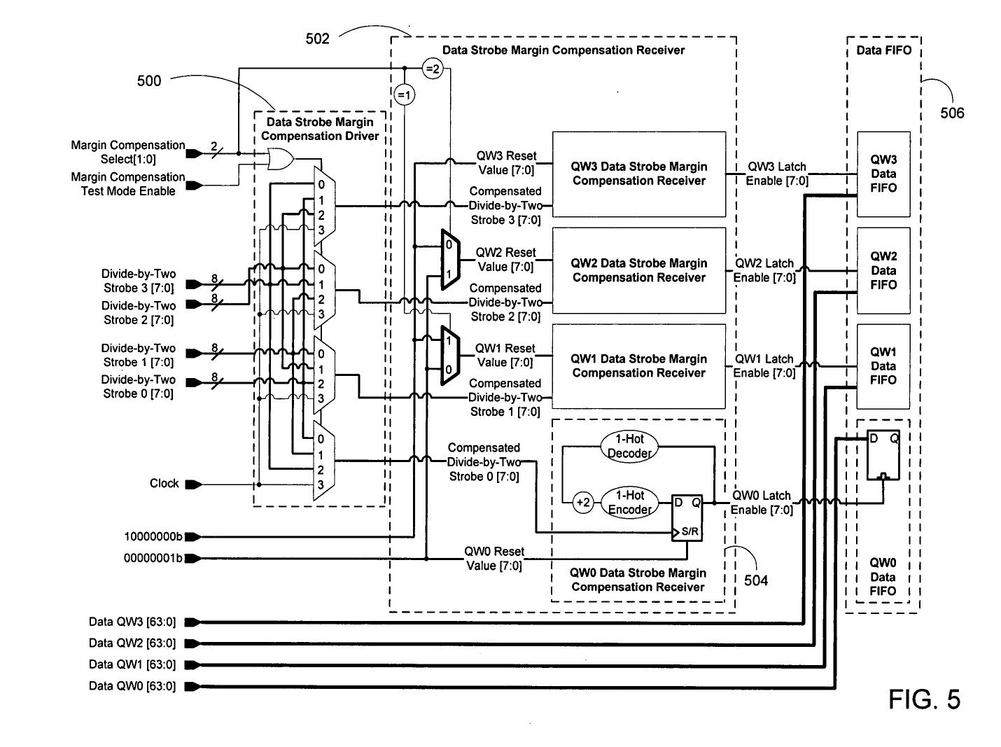

FIG. 5 illustrates one embodiment of the detailed circuitry within the Data Strobe Margin Compensation Driver and the Data Strobe Margin Compensation Receiver. In one embodiment, the Data Strobe Margin Compensation Driver 500 receives the four divide-by-two strobe outputs from the Data Window Enlargement and Data Strobe Divider as inputs. Furthermore, in this embodiment, the Data Strobe Margin Compensation Driver 500 also receives a 2-bit Margin Compensation Select value and a 1-bit Margin Compensation Test-Mode Enable value as additional inputs.

As referred to above in reference to FIG. 2, in one embodiment, the 1-bit Margin Compensation Test-Mode Enable value determines whether the margin compensation logic is activated and will be allowed to latch data with the divide-by-two strobes 0-3. The Margin Compensation Select value determines whether each divide-by-two strobe will operate at nominal timing (I.e. the incoming data strobe and incoming data are already matched), delayed timing (I.e. the incoming data strobe is early in regard to its corresponding incoming data so a delay on the strobe will match the data and strobe), or early timing (I.e. the incoming data strobe is delayed in regard to its corresponding incoming data so modifying the strobe to come earlier will match the data and strobe). Table 1 above illustrates the available Margin Compensation Select values and the corresponding data strobe timing.

The Data Strobe Margin Compensation Driver 500 generates and sends out compensated modified data strobes 0-3 that correspond to each QW of the data located on the four Internal Data Interconnects. Each compensated modified data strobe is a multiplexed version of the divide-by-2 modified data strobe generated from the Data Window Enlargement and Data Strobe Divider. The Margin Compensation Select value is used at each of the four multiplexers within the Data Strobe Margin Compensation Driver 500 to select either a nominal, early or delayed divide-by-2 strobe for the corresponding QW data on that byte lane.

The four compensated divide-by-two strobes that are generated are sent to the Data Strobe Margin Compensation Receiver 502. The Data Strobe Margin Compensation Receiver 502 has a receiver block to receive the compensated divide-by-two strobes corresponding to each of the four data QWs located on the four Internal Data Interconnects. The receiver block for the QW0 strobe is detailed in FIG. 5 (Item 504). The Data Strobe Margin Compensation Receiver 502 utilizes the compensated divide-by-two strobes as inputs to generate latch enables to latch the corresponding QW data in each QW FIFO buffer. In one embodiment, the latch enables are 8-bit values that correspond to the eight locations in each QW FIFO buffer. For example, to latch data into location 1 of a QW FIFO buffer, the latch enable value would be 00000001b. Alternatively, to latch data into location 8 of a QW FIFO buffer, the latch enable would be 10000000b. Therefore, each bit of the value corresponds to one of the eight QW FIFO buffer storage locations and the single bit that is a “1” refers to which storage location to latch the data to. Each receiver block has a flop that receives the compensated divide-by-two strobe as the clock input. The flop's output is the latch enable value. Thus, the flop changes the latch enable value once per compensated divide-by-two strobe cycle.

Additionally, each Data Strobe Margin Compensation Receiver 502 block (I.e. blocks 0-3 for QWs 0-3) has a decoder, an incrementer, and an encoder. The flop output is not only sent to the QW FIFO buffer 506 as the latch enable value, but it also is sent to the decoder to decode the value into standard binary value. The decoded value is then incremented to the next consecutive latch enable value (E.g. 00000010b would increment to 00000100b), and the new value is encoded back into the 8-bit latch enable value format for use by the flop as the next output, which occurs on the next compensated divide-by-two strobe cycle.

Each receiver block in the Data Strobe Margin Compensation Receiver 502 also receives as input a latch enable reset value for each QW receiver block. The reset value corresponds to the initial latch enable value utilized for each QW block. Due to timing requirements put in place with the stretched data, in certain circumstances the first rising edge of the compensated divide-by-two strobe will occur prior to valid data being in place on the corresponding IDI. Normally, if the data is valid, the data will be latched in storage location 1 of the eight location deep FIFO (00000001b). But, in this case, the reset value may force the first invalid QW of data to latch into storage location 8 (10000000b). Then, once the data becomes valid, the input to the flop has gone through a decoder-incrementer-encoder sequence, as described above, and the first valid QW of data for that particular IDI will latch into QW FIFO buffer storage location 1 (I.e. incrementing from location 8 will return the latch enable value to location 1).

Due to timing restrictions, in the present embodiment, the compensated divide-by-two strobes' reset values are always known for the strobes corresponding to data located in Internal Data Interconnect 0 and Internal Data Interconnect 3. Specifically, regardless of whether nominal, early, or late timing is utilized, the data on Internal Data Interconnect 0 will always be valid during the initial strobe cycle. Thus, Internal Data Interconnect 0 will always utilize the latch enable reset value for storage location 1 during the initial strobe cycle. Contrary to Internal Data Interconnect 0, the data on Internal Data Interconnect 3 will always be invalid during the initial strobe cycle. Thus, Internal Data Interconnect 3 will always utilize the latch enable reset value for storage location 8 during the initial strobe cycle.

The validity of the data during the initial strobe cycle on Internal Data Interconnect 1 and Internal Data Interconnect 2 is dependent upon whether the nominal, early, or delayed compensated strobe settings are utilized. Thus, a multiplexer is used to input the correct initial latch enable value (either 00000001b or 10000000b). The determining factor of which one is used for the latch enables corresponding to the Internal Data Interconnect 1 and Internal Data Interconnect 2 data is the divide-by-two strobe input into the Data Strobe Margin Compensation Receiver.

Thus, the Data Strobe Margin Compensation Receiver outputs the latch enable values from blocks 0-3 to the corresponding four QW FIFO buffers. The buffers then utilize the latch enables to latch the data located on each of the four Internal Data Interconnects into the specified storage locations (specified by the latch enable values) within the each QW FIFO buffer. Once the data is in place within the QW FIFO buffer, the data may be sent to initial data requestor. This may occur at the same rate as the data coming in from the processor-memory interconnect.

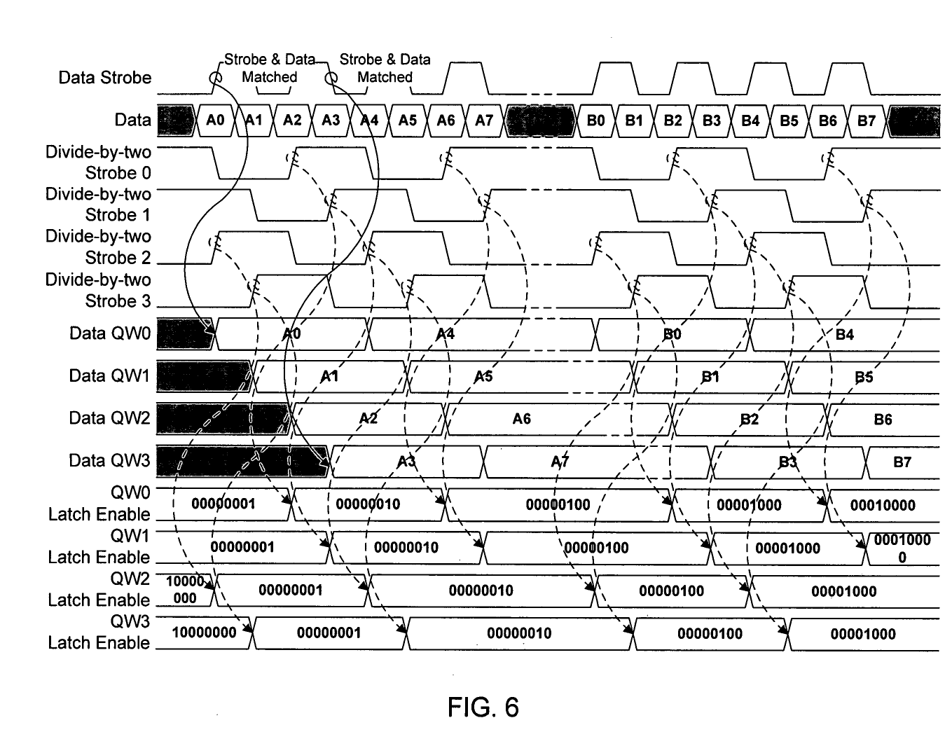

FIG. 6 illustrates a timing diagram of one embodiment of the compensated divide-by-two strobes, the data, and the latch enables in a nominal strobe timing mode. In the nominal strobe timing mode the data and the strobe are already matched, thus no strobe compensation is necessary. Additionally, in the nominal strobe timing mode the initial data on Internal Data Interconnect 2 is not valid, thus the latch enable reset value for QW2 that is fed into the QW2 Receiving Block is 10000000b, the first valid data on Internal Data Interconnect 2 is latched with the second rising edge of the divide-by-two strobe for QW2.

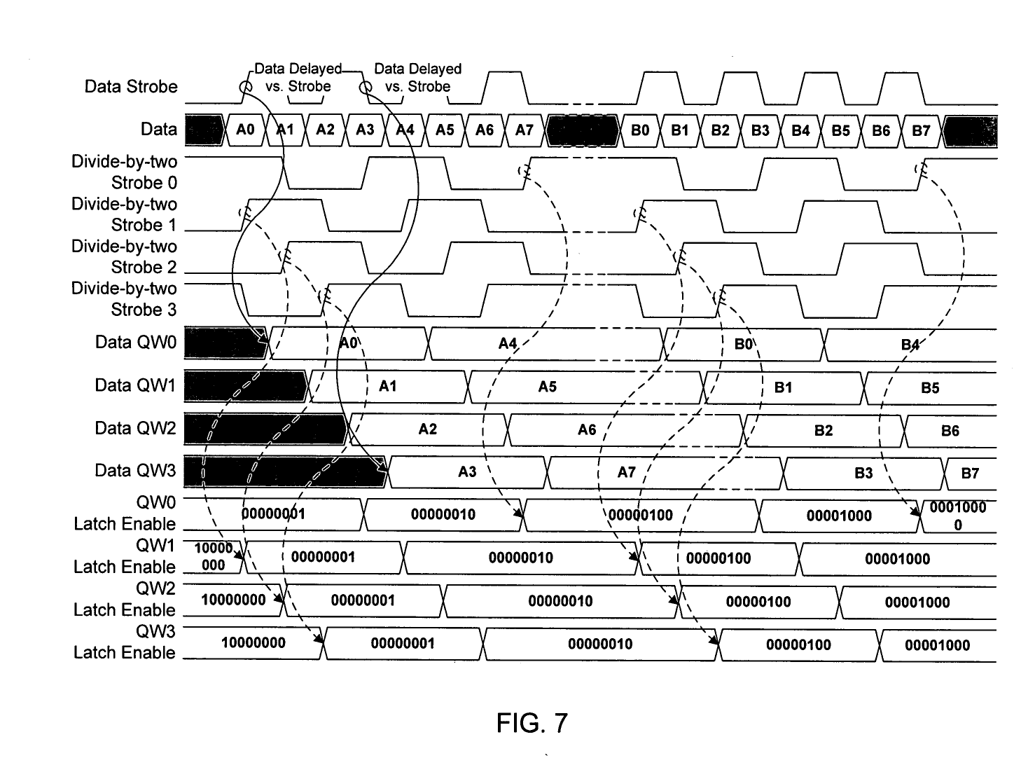

FIG. 7 illustrates a timing diagram of one embodiment of the compensated divide-by-two strobes, the data, and the latch enables in a delayed strobe timing mode. In this timing diagram, the data is delayed in relationship to the strobe. Thus, the compensated divide-by-two strobes are delayed to realign with the data. In the delayed timing mode the initial data on Internal Data Interconnect 1 is not valid, thus the latch enable reset value for QW1 that is fed into the QW1 Receiving Block is 10000000b, the first valid data on Internal Data Interconnect 1 is latched with the second rising edge of the divide-by-two strobe for QW1.

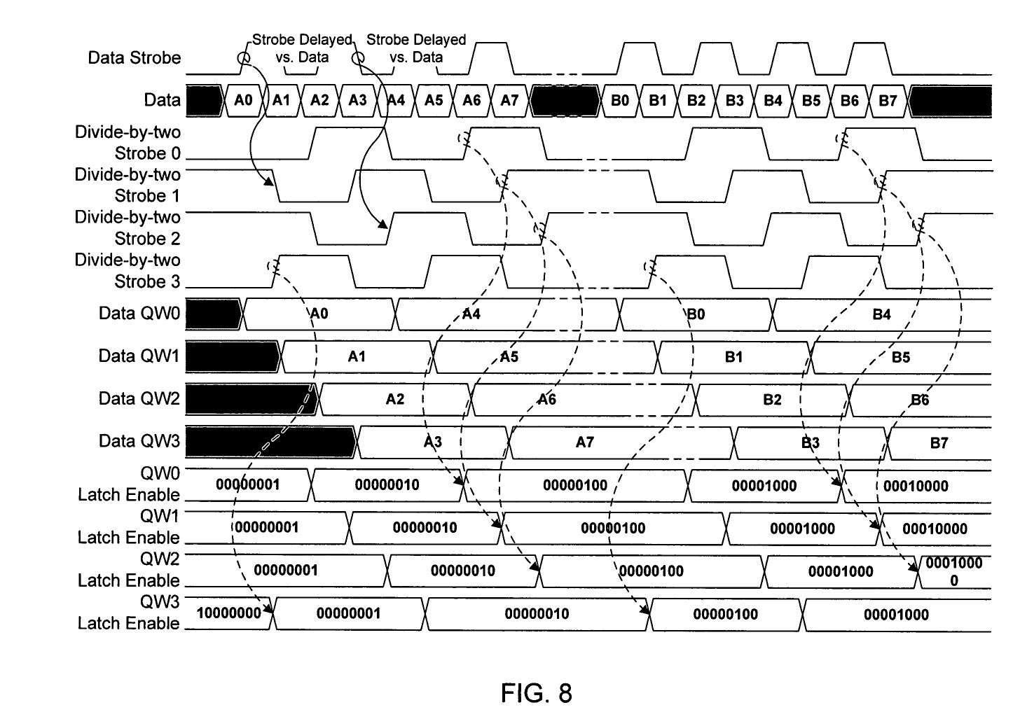

FIG. 8 illustrates a timing diagram of one embodiment of the compensated divide-by-two strobes, the data, and the latch enables in an early strobe timing mode. In this timing diagram, the data is early in relationship to the strobe. Thus, the compensated divide-by-two strobes are input early to realign with the data. In the early timing mode the initial data on all four Internal Data Interconnects are valid, thus all four QWs are latched on the first rising edge of their respective divide-by-two strobe.

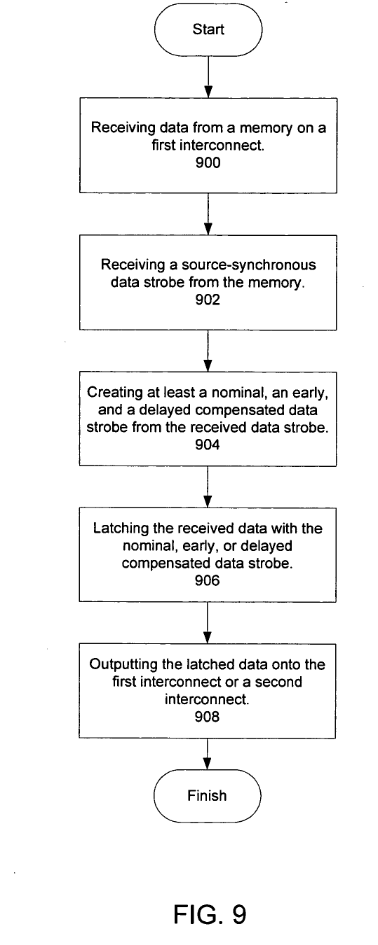

FIG. 9 is a flow diagram of one embodiment of a process to compensate for mismatched timing between data and a source synchronous data strobe. The process is performed by processing logic that may comprise hardware (circuitry, dedicated logic, etc.), software (such as is run on a general purpose computer system or a dedicated machine), or a combination of both. Referring to FIG. 9, the process begins by processing logic receiving data from a memory on a first interconnect. In one embodiment, the first interconnect is a computer system's processor memory interconnect and the data is sent onto the interconnect from the system memory coupled to the interconnect (processing block 900).

The process continues with processing logic receiving a source-synchronous data strobe from the memory (processing block 902). Then processing logic creates at least a nominal, an early, and a delayed compensated data strobe from the received data strobe (processing block 904). In one embodiment, the nominal, early, and delayed data strobes are divide-by-two strobes. The divide-by-two strobes are created by sampling every other rising or falling edge of the received data strobe.

Processing logic then latches the received data with the nominal, early, or delayed compensated data strobe (processing block 906). In one embodiment, the data is latched with the nominal compensated strobe if the received data and received data strobe have matching timing, the data is latched with the delayed compensated strobe if the received data is received later than the corresponding received strobe, and the data is latched with the early compensated strobe if the received data is received prior to the corresponding received strobe. Finally, the latched data is output onto the first interconnect or a second interconnect (processing block 908) and the process is finished. In different embodiments, the data may stay on the processor-memory interconnect if the memory read was requested by the processor or the data may transfer onto a second interconnect if the memory read was requested by a bus master device on an I/O interconnect. There are many different master devices that may send a read request to the memory.

Thus, embodiments of a method, apparatus, and system to compensate for a timing mismatch between data and a source-synchronous data strobe are described. These embodiments have been described with reference to specific exemplary embodiments thereof. It will be evident to persons having the benefit of this disclosure that various modifications and changes may be made to these embodiments without departing from the broader spirit and scope of the embodiments described herein. The specification and drawings are, accordingly, to be regarded in an illustrative rather than a restrictive sense.

What is claimed is:

1. A method, comprising:
receiving data from a memory on a first interconnect of at least one interconnect;
receiving a source-synchronous data strobe from the memory;
creating at least a nominal, an early, and a delayed compensated data strobe from the received data strobe;
latching the received data with the nominal, early, or delayed compensated data strobe;
outputting the latched data onto one or more of the at least one interconnect.

2. The method of claim 1, further comprising selecting the nominal, early, or delayed compensated data strobe to latch the received data based on the alignment between the received data and the received data strobe.

3. The method of claim 2, further comprising:
splitting the compensated data strobe into four divide-by-two strobes, each created from sampling the received data strobe on every other rising or falling edge; and
splitting the received data onto four separate internal interconnects entering a buffer, wherein each of the four internal interconnects holds every fourth unit of data sent across the memory interconnect.

4. The method of claim 3, wherein the four divide-by-two strobes are quad-staggered, each latching every fourth unit of data entering the buffer.

5. The method of claim 4, wherein the quad-staggered divide-by-two strobes are each staggered one-half of a received data strobe cycle apart from the previous divide-by-two strobe.

6. The method of claim 3, further comprising holding each unit of data valid for two full cycles of the received data strobe on the associated internal interconnect.

7. An apparatus, comprising:
a buffer to store data;
a data strobe tolerance unit operable to:
receive data from a memory across a first interconnect of at least one interconnect;
receive a source-synchronous data strobe from the memory;
create at least a nominal, an early, and a delayed compensated data strobe from the received data strobe;
select the nominal, early, or delayed compensated data strobe, based on the timing alignment between the received data and the received data strobe, to latch the received data in the buffer; and
output the received data from the buffer to one or more of the at least one interconnect.

8. The apparatus of claim 7, wherein the data strobe tolerance unit is further operable to:
split the compensated data strobe into four divide-by-two strobes, each created from sampling the received data strobe on every other rising or falling edge; and
split the received data onto four separate internal interconnects entering the buffer, wherein each of the four internal interconnects holds every fourth unit of data sent across the first external interconnect.

9. The apparatus of claim 8, wherein the four divide-by-two strobes are quad-staggered, each operable to latch every fourth unit of data entering the buffer.

10. The apparatus of claim 9, wherein the quad-staggered divide-by-two strobes are each staggered one-half of a received data strobe cycle apart from the previous divide-by-two strobe.

11. The apparatus of claim 10, wherein the data strobe tolerance logic is further operable to hold each unit of data valid on the associated internal interconnect for two full cycles of the received data strobe.

12. The apparatus of claim 8, wherein the data strobe tolerance logic is further operable to hold each unit of data valid on the associated internal interconnect until the fourth unit of data following the given single unit of data is received from the first interconnect.

13. The apparatus of claim 8, wherein the unit of data is 8 bytes wide.

14. A system, comprising:
an interconnect;
a processor coupled to the interconnect;
a memory coupled to the interconnect;
a chipset coupled to the interconnect, wherein the chipset further comprises data strobe tolerance logic to:
receive data from the memory across the interconnect;
receive a data strobe from the memory;
create at least a nominal, an early, and a delayed compensated data strobe from the received data strobe;
select the nominal, early, or delayed compensated data strobe, based on the timing alignment between the received data and the received data strobe, to latch the received data in a buffer; and
output the received data from the buffer to the interconnect;
a second interconnect coupled to the chipset; and
a network interface card coupled to the second interconnect.

15. The system of claim 14, wherein the data strobe tolerance logic is further operable to:
split the compensated data strobe into four divide-by-two strobes, each created from sampling the received data strobe on every other rising or falling edge; and
split the received data onto four separate internal interconnects entering the buffer, wherein each of the four internal interconnects holds every fourth unit of data sent across the interconnect coupled to the memory.

16. The system of claim 15, wherein the four divide-by-two strobes are quad-staggered, each operable to latch every fourth unit of data entering the buffer.

17. The system of claim 16, wherein the quad-staggered divide-by-two strobes are each staggered one-half of a received data strobe cycle apart from the previous divide-by-two strobe.

18. The system of claim 17, wherein the data strobe tolerance logic is further operable to hold each unit of data valid on the associated internal interconnect for two full cycles of the received data strobe.

19. The system of claim 15, wherein the data strobe tolerance logic is further operable to hold each unit of data valid on the associated internal interconnect until the fourth unit of data following the given single unit of data is received from the first interconnect.

20. The system of claim 15, wherein the unit of data is 8 bytes wide
